(19) United States
(12) Patent Application Publication
(10) Pub. No.: US 2025/0351403 A1
(43) Pub. Date: Nov. 13, 2025

(54) SEMICONDUCTOR DEVICE AND METHOD

(71) Applicant: Taiwan Semiconductor Manufacturing Co., Ltd., Hsinchu (TW)

(72) Inventor: Yu-Lien Huang, Jhubei (TW)

(21) Appl. No.: 19/274,588

(22) Filed: Jul. 20, 2025

Related U.S. Application Data
(62) Division of application No. 17/651,099, filed on Feb. 15, 2022.
(60) Provisional application No. 63/254,765, filed on Oct. 12, 2021.

(51) Int. Cl. H10D 30/01; H10D 30/62; H10D 62/10; H10D 84/01; H10D 84/03; H10D 84/83

(52) U.S. Cl. CPC H10D 30/024; H10D 30/6211; H10D 30/6219; H10D 62/116; H10D 84/013; H10D 84/0151; H10D 84/0158; H10D 84/038; H10D 84/834

(57) ABSTRACT

A method includes forming an isolation region around a semiconductor fin; forming a gate structure over the semiconductor fin; forming a source/drain region in the semiconductor fin adjacent the gate structure; depositing a metal material covering the isolation region, the gate structure, the semiconductor fin, and the source/drain region; etching openings in the metal material, wherein each opening exposes the isolation region, wherein the metal material remains on a top surface of the source/drain region remains after etching the openings; and depositing an insulating material, wherein the insulating material fills the openings.

### PRIORITY CLAIM AND CROSS-REFERENCE

This application is a divisional of U.S. patent application Ser. No. 17/651,099, filed on Feb. 15, 2022, which claims the benefits of U.S. Provisional Application No. 63/254,765, filed on Oct. 12, 2021, each application is hereby incorporated herein by reference in its entirety.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1, 2, 3, 4, 5, 6, 7, 8, 9, and 10 illustrate perspective views of intermediate stages in the formation of a FinFET device, in accordance with some embodiments of the present disclosure.

FIGS. 11A and 11B illustrate cross-sectional views of intermediate stages in the formation of a FinFET device, in accordance with some embodiments of the present disclosure.

FIGS. 12, 13A, 13B, 14, 15A, 15B, 16A, 16B, 17A, 17B, 18A, 18B, 19A, 19B, 20A, 20B, 21A, 21B, 22A, 22B, 23, 24A, and 24B illustrate perspective views and cross-sectional views of intermediate stages in the formation of source/drain contacts of a FinFET device, in accordance with some embodiments of the present disclosure.

FIG. 25 illustrates a cross-sectional view of an intermediate stage in the formation of a FinFET device, in accordance with some embodiments of the present disclosure.

FIGS. 26, 27A, 27B, 27C, 28, 29A, 29B, 29C, 30, 31A, 31B, and 31C illustrate cross-sectional views of intermediate stages in the formation of source/drain contacts of a FinFET device, in accordance with some embodiments of the present disclosure.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Source/drain contacts of a Fin Field-Effect Transistor (FinFET) and methods of forming the same are provided in accordance with some embodiments. The intermediate stages of forming the contacts are illustrated in accordance with some embodiments. Some variations of some embodiments are discussed. Throughout the various views and illustrative embodiments, like reference numbers are used to designate like elements. In accordance with some embodiments, source/drain contacts are formed by depositing conductive material and then patterning the conductive material to define the source/drain contacts. By depositing the conductive material for patterning, the conductive material may be formed having larger metal grains, which can reduce the resistance of the conductive material. Additionally, using the techniques herein, the patterned conductive material may be formed contacting a larger area of the source/drain, which can reduce the contact resistance of the source/drain contacts.

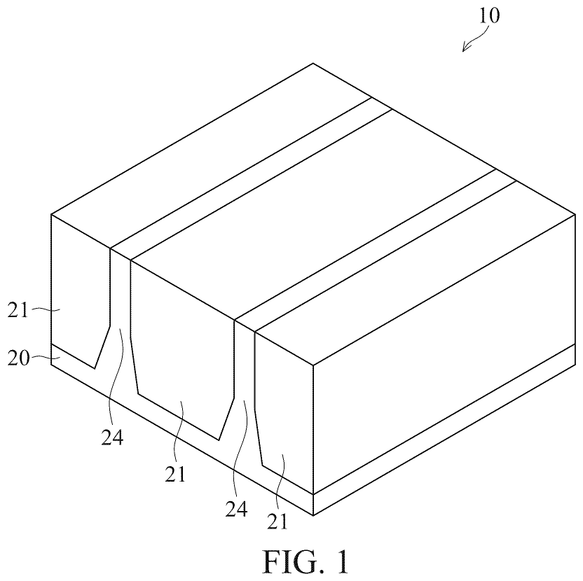

FIG. 1 illustrates a perspective view of an initial structure, in accordance with some embodiments. The initial structure includes a wafer 10, which further includes a substrate 20. The substrate 20 may be a semiconductor substrate, such as a bulk semiconductor, a semiconductor-on-insulator (SOI) substrate, or the like, which may be doped (e.g., with a p-type or an n-type dopant) or undoped. The substrate 20 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 20 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof.

Fins 24 may be formed in the substrate 20, in accordance with some embodiments. In some embodiments, the fins 24 may be formed in the substrate 20 by etching trenches in the substrate 20. The etching may be any acceptable etch process, such as a reactive ion etch (RIE), neutral beam etch (NBE), the like, or a combination thereof. The etch may be anisotropic. In other embodiments, the fins 24 are replacement strips formed by etching portions of the substrate 20 to form recesses and forming another semiconductor material in the recesses using an epitaxial growth process. Accordingly, the fins 24 may be formed of a semiconductor material different from that of the substrate 20.

The fins 24 may be patterned using any suitable method. For example, the fins 24 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over the substrate 20 and patterned using a photolithography process. Spacers are formed alongside the patterned sacrificial layer using a self-aligned process. The sacrificial layer is then removed, and the remaining spacers, or mandrels, may then be used to pattern the fins 24.

An insulation material 21 may be formed over the substrate 20 and between neighboring fins 24, in accordance with some embodiments. The insulation material 21 may be an oxide, such as silicon oxide, a nitride, the like, or a combination thereof. The insulation material 21 may be formed using a suitable process such as atomic layer deposition (ALD), chemical vapor deposition (CVD), high-density plasma chemical vapor deposition (HDPCVD), flowable CVD (FCVD), spin-coating, the like, or a combination thereof. Other insulation materials formed by any acceptable process may be used. In the illustrated embodiment, the insulation material 21 is silicon oxide formed by a FCVD process. An anneal process may be performed once the insulation material 21 is formed. In an embodiment, the insulation material 21 is formed such that excess insulation material 21 covers the fins 24. Although the insulation material 21 is illustrated as a single layer, some embodiments may utilize multiple layers. For example, in some embodiments a liner (not shown) may first be formed along a surface of the substrate 20 and the fins 24. Thereafter, a fill material such as those discussed above may be formed over the liner. A planarization process may be performed to remove excess insulation material 21 over the fins 24, in some embodiments. The planarization process may comprise one or more techniques such as a chemical mechanical polish (CMP), grinding, an etch-back process, combinations thereof, or the like. In some embodiments, the planarization process exposes the fins 24 such that top surfaces of the fins 24 and the insulation material 21 are substantially level.

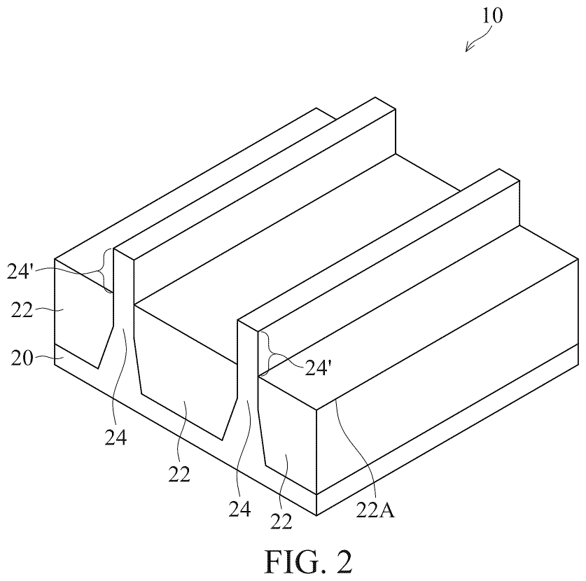

Referring to FIG. 2, the insulation material 21 is recessed to form Shallow Trench Isolation (STI) regions (isolation regions 22), in accordance with some embodiments. In some embodiments, the top portions 24′ of the fins 24 protrude higher than the top surfaces 22A of the isolation regions 22. The protruding portions of the fins 24 are referred to herein as channel regions 24′. Further, the top surfaces of the isolation regions 22 may have a flat surface as illustrated, a convex surface, a concave surface (such as dishing), or a combination thereof. The top surfaces of the isolation regions 22 may be formed flat, convex, and/or concave by an appropriate etch. The isolation regions 22 may be recessed using an acceptable etching process, such as one that is selective to the material of the insulation material 21 (e.g., etches the material of the insulation material 21 at a faster rate than the material of the fins 24). The etching process may include a wet etching process and/or a dry etching process.

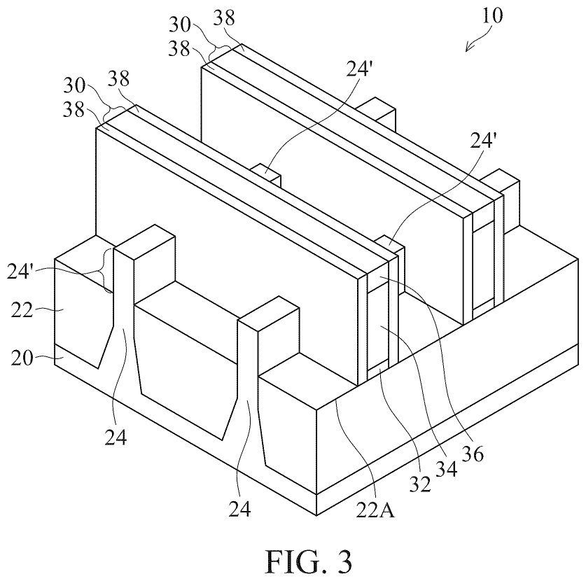

Referring to FIG. 3, dummy gate stacks 30 and gate spacers 38 are formed, in accordance with some embodiments. In some embodiments, a dummy dielectric layer may first be formed on the fins 24. The dummy dielectric layer may be, for example, silicon oxide, silicon nitride, a combination thereof, or the like, and may be deposited or thermally grown according to acceptable techniques. A dummy gate layer is formed over the dummy dielectric layer, and a mask layer is formed over the dummy gate layer. The dummy gate layer may be deposited over the dummy dielectric layer and then planarized, such as by a CMP. The mask layer may then be deposited over the dummy gate layer. The mask layer may be a single layer or may include multiple layers of different materials. The mask layer may be patterned using acceptable photolithography and etching techniques to form masks 36. The pattern of the masks 36 then may be transferred to the dummy gate layer to form dummy gates 34. In some embodiments (not illustrated), the pattern of the masks 36 may also be transferred to the dummy dielectric layer by an acceptable etching technique to form gate dielectric layer 32. Together the gate dielectric layer 32 and dummy gates 34 form dummy gate stacks 30. The dummy gate stacks 30 cover respective channel regions 24′ of the fins 24. The pattern of the masks 36 may be used to physically separate each of the dummy gate stacks 30 from adjacent dummy gate stacks 30. The dummy gate stacks 30 may also have a lengthwise direction substantially perpendicular to the lengthwise direction of respective fins 24.

The dummy gates 34 may be a conductive or non-conductive material and may be selected from a group including amorphous silicon, polycrystalline-silicon (polysilicon), poly-crystalline silicon-germanium (poly-SiGe), metallic nitrides, metallic silicides, metallic oxides, and metals. The dummy gates 34 formed from the dummy gate layer may be deposited by physical vapor deposition (PVD), CVD, sputter deposition, or other techniques known and used in the art for depositing the selected material. The dummy gates 34 may be made of other materials that have a high etching selectivity from the etching of isolation regions 22. The mask 36 formed from the mask layer may comprise one or more layers of suitable material(s) such as silicon oxide, silicon nitride, silicon oxynitride, silicon carbonitride, the like, or a combination thereof.

Gate spacers 38 are then be formed on the sidewalls of the dummy gate stacks 30, in accordance with some embodiments. The gate spacers 38 may be formed of one or more layers of dielectric materials such as silicon nitride, silicon oxide, silicon carbonitride, silicon oxynitride, silicon oxycarbonitride, the like, or a combination thereof. In some embodiments, the gate spacers 38 may be formed by conformally depositing a dielectric material and then anisotropically etching the dielectric material.

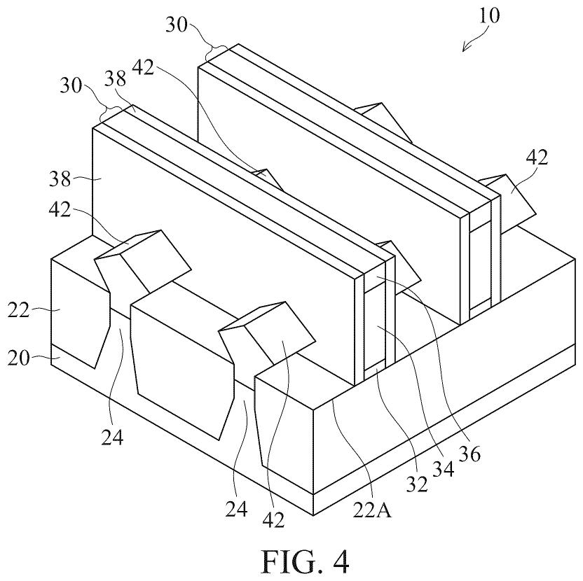

Turning to FIG. 4, epitaxial source/drain regions 42 are formed in the fins 24, in accordance with some embodiments. The epitaxial source/drain regions 42 are formed in the fins 24 such that each dummy gate stack 30 is disposed between respective neighboring pairs of the epitaxial source/drain regions 42. In some embodiments, the epitaxial source/drain regions 42 may extend into the fins 24 and may also penetrate through the fins 24. In some embodiments, the gate spacers 38 separate the epitaxial source/drain regions 42 from the dummy gate stacks 30 by an appropriate lateral distance such that the epitaxial source/drain regions 42 do not short out subsequently formed gates of the resulting FinFETs. A material of the epitaxial source/drain regions 42 may be selected to exert stress in the respective channel regions 24′, thereby improving performance.

In some embodiments, the epitaxial source/drain regions 42 may be formed by etching source/drain regions of the fins 24 to form recesses in the fins 24. Then, the epitaxial source/drain regions 42 are epitaxially grown in the recesses. The epitaxial source/drain regions 42 may include any acceptable material, such as appropriate for n-type FinFETs and/or p-type FinFETs. For example, if the fin 24 is silicon, the epitaxial source/drain regions 42 of an n-type FinFET may include materials exerting a tensile strain in the channel region 24′, such as silicon, silicon carbide, phosphorous-doped silicon carbide, silicon phosphide, or the like. For example, if the fin 24 is silicon, the epitaxial source/drain regions 42 of a p-type FinFET may comprise materials exerting a compressive strain in the channel region 24′, such as silicon-germanium (SiGe), boron-doped silicon-germanium, germanium, germanium tin, or the like. In accordance with alternative embodiments of the present disclosure, the epitaxial source/drain regions 42 are formed of a III-V compound semiconductor such as GaAs, InP, GaN, InGaAs, InAlAs, GaSb, AlSb, AlAs, AlP, GaP, combinations thereof, or multi-layers thereof. Epitaxial source/drain regions 42 may include lower portions that are formed in the isolation regions 22 and upper portions that are formed over the top surfaces of isolation regions 22, in some embodiments. The epitaxial source/drain regions 42 may have surfaces raised from respective surfaces of the fins 24 and may have facets.

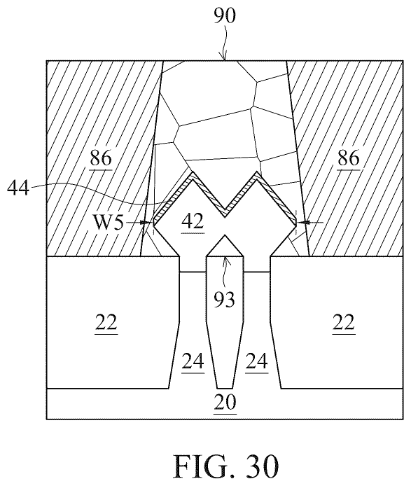

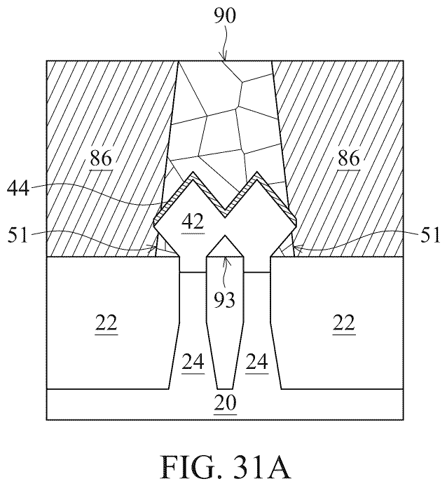

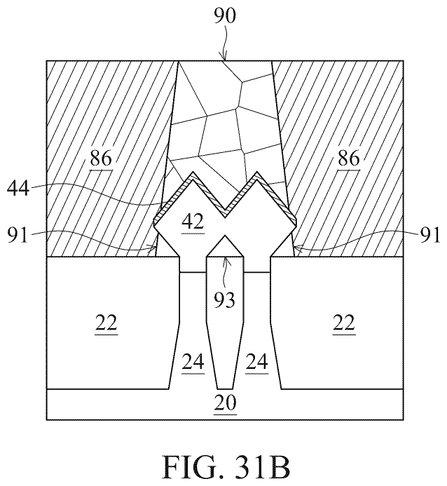

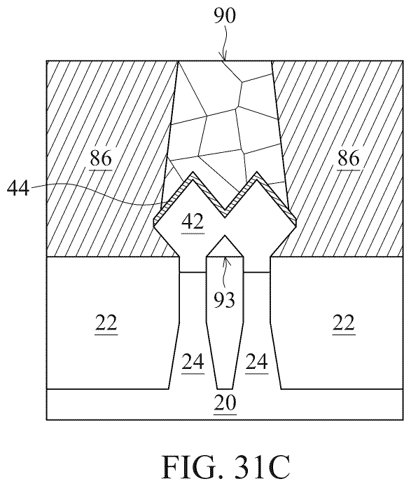

The epitaxial source/drain regions 42 and/or the fins 24 may be implanted with dopants to form source/drain regions, which may be followed by an anneal. In some embodiments, the epitaxial source/drain regions 42 may be in situ doped during growth. As a result of the epitaxy processes used to form the epitaxial source/drain regions 42, upper surfaces of the epitaxial source/drain regions may have facets which expand laterally outward beyond sidewalls of the fins 24. In some embodiments, these facets cause adjacent source/drain regions 42 of a same FinFET to merge. Example embodiments with merged source/drain regions 42 are described below for FIGS. 30 and 31A-31C. In other embodiments, adjacent source/drain regions 42 remain separated after the epitaxy process is completed, as illustrated by FIG. 4.

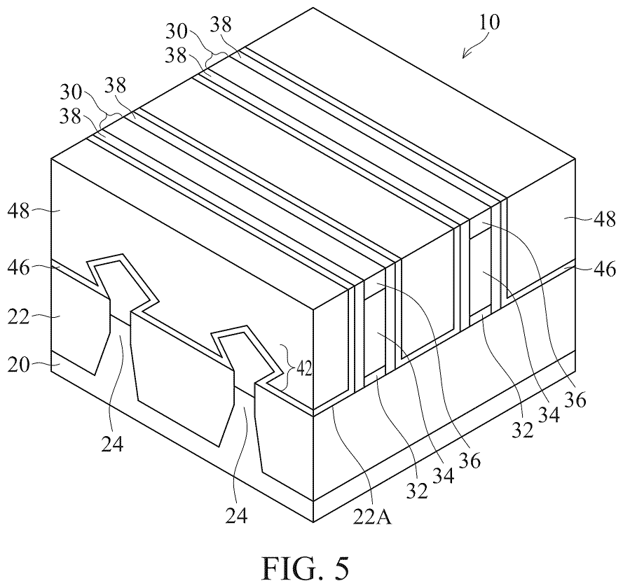

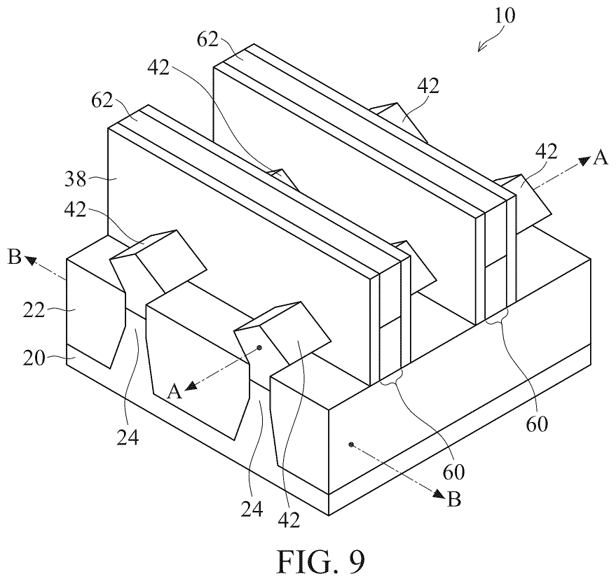

In FIG. 5, a dielectric layer 48 is deposited over the structure illustrated in FIG. 4, in accordance with some embodiments. The dielectric layer 48 is removed in a subsequent step (see FIG. 9), and thus may be considered a “dummy Inter-layer Dielectric (ILD) layer” or a “sacrificial layer” in some cases. The dielectric layer 48 may be formed of one or more dielectric materials, and may be deposited using any suitable method, such as CVD, plasma-enhanced CVD (PECVD), or FCVD. The dielectric materials may include silicon oxide, phospho-silicate glass (PSG), boro-silicate glass (BSG), boron-doped phospho-silicate glass (BPSG), undoped silicate glass (USG), or the like. Other dielectric materials formed by any acceptable process may be used in other embodiments. In some embodiments, a bottom etch stop layer (BESL) 46 is disposed between the dielectric layer 48 and the epitaxial source/drain regions 42, the masks 36, and the gate spacers 38. The BESL 46 may comprise a dielectric material, such as silicon nitride, silicon oxide, silicon oxynitride, or the like, having a different etch rate than the material of the overlying the dielectric layer 48.

In some embodiments, a planarization process, such as a CMP or the like, may be performed to level the top surface of the dielectric layer 48 with the top surfaces of the dummy gate stacks 30 or the masks 36. The planarization process may also remove the masks 36 (or a portion thereof) on the dummy gate stacks 30, and portions of the gate spacers 38 along sidewalls of the masks 36. After the planarization process, the masks 36 may remain, in which case top surfaces of the masks 36, top surfaces of the gate spacers 38, and the top surface of the dielectric layer 48 may be level, as illustrated in FIG. 5. In other embodiments, the masks 36 are removed by the planarization process, and the top surfaces of the dummy gate stacks 30, the gate spacers 38, and the dielectric layer 48 may be level. In these embodiments, the top surfaces of the dummy gates 34 are exposed through the dielectric layer 48 after performing the planarization process.

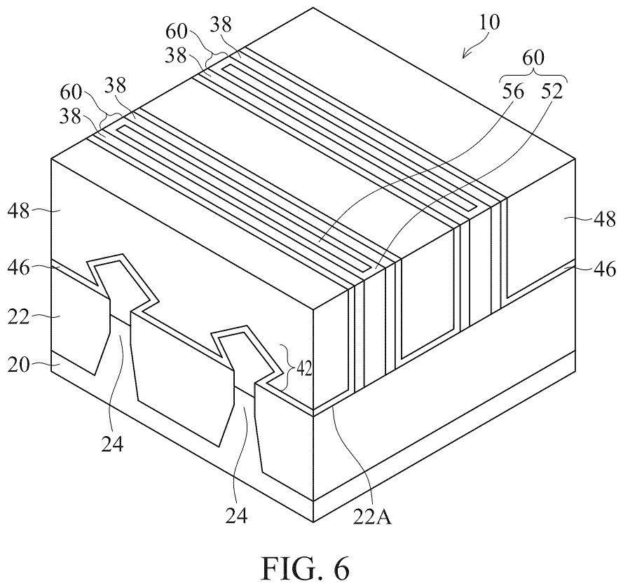

In FIG. 6, the dummy gates 34, the masks 36 (if present), and optionally the gate dielectric layer 32, are removed in one or more etching steps and replaced with replacement gates. In some embodiments, the masks 36 (if present) and the dummy gates 34 are removed using an anisotropic dry etching process. For example, the etching process may include a dry etching process using reaction gas(es) that selectively etch the masks 36 and the dummy gates 34 without etching the dielectric layer 48 or the gate spacers 38. Each recess exposes and/or overlies a channel region 24′ of a respective fin 24 (e.g., the upper portion of the fin 24). During the removal, the gate dielectric layer 32 may be used as an etch stop layer when the dummy gates 34 are etched. The gate dielectric layer 32 may then be optionally removed after the removal of the dummy gates 34.

Next, gate dielectric layers 52 and gate electrodes 56 are formed as replacement gates, in accordance with some embodiments. The gate dielectric layers 52 are deposited conformally in the recesses, such as on the top surfaces and the sidewalls of the fins 24 and on the sidewalls of the gate spacers 38. The gate dielectric layers 52 may also be formed on the top surface of the dielectric layer 48, in some cases. In accordance with some embodiments, the gate dielectric layers 52 comprise silicon oxide, silicon nitride, or multilayers thereof. In some embodiments, the gate dielectric layers 52 comprise a high-k dielectric material. In these embodiments, the gate dielectric layers 52 may have a k value greater than about 7.0 and may include a metal oxide or a silicate of hafnium, aluminum, zirconium, lanthanum, manganese, barium, titanium, lead, the like, or combinations thereof. The gate dielectric layers 52 may be formed using one or more suitable techniques, such as Molecular-Beam Deposition (MBD), ALD, CVD, PECVD, the like, or combinations thereof. For embodiments in which portions of the gate dielectric layer 32 remain in the recesses, the gate dielectric layers 52 may include a material of the gate dielectric layer 32 (e.g., silicon oxide).

The gate electrodes 56 are deposited over the gate dielectric layers 52 and may fill remaining portions of the recesses. The gate electrodes 56 may include a metal-containing material such as titanium nitride, titanium oxide, tantalum nitride, tantalum carbide, cobalt, ruthenium, aluminum, tungsten, the like, combinations thereof, or multi-layers thereof. For example, although the gate electrode 56 is illustrated in FIG. 6 as having a single layer, the gate electrode 56 may comprise any number of liner layers, any number of interfacial layers, any number of work-function tuning layers, and/or a fill material, which are collectively illustrated as the gate electrode 56. The gate electrodes 56 may be formed using one or more suitable techniques, such as ALD, CVD, the like, or combinations thereof. After the filling of the recesses, a planarization process, such as a CMP, may be performed to remove the excess portions of the gate dielectric layers 52 and the material of the gate electrodes 56, which excess portions are over the top surface of the dielectric layer 48. The remaining portions of material of the gate dielectric layers 52 and the gate electrodes 56 thus form replacement gates of the resulting FinFETs. The gate electrodes 56 and the gate dielectric layers 52 of the replacement gates are collectively referred to herein as gate stacks 60. The gate stacks 60 may extend along sidewalls of channel regions 24′ of the fins 24.

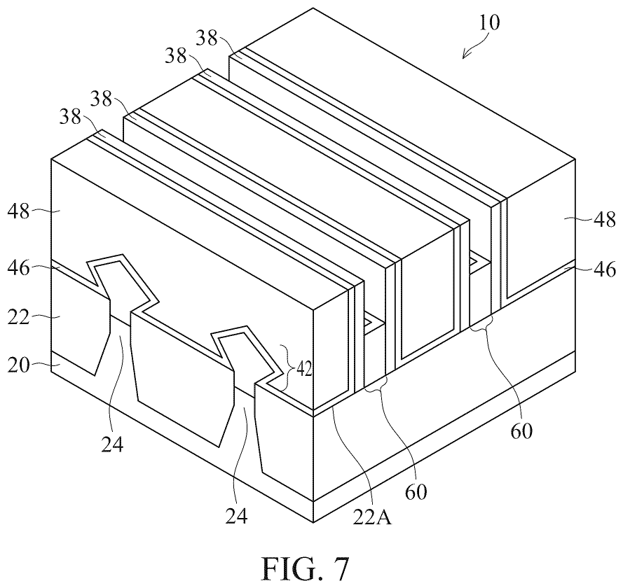

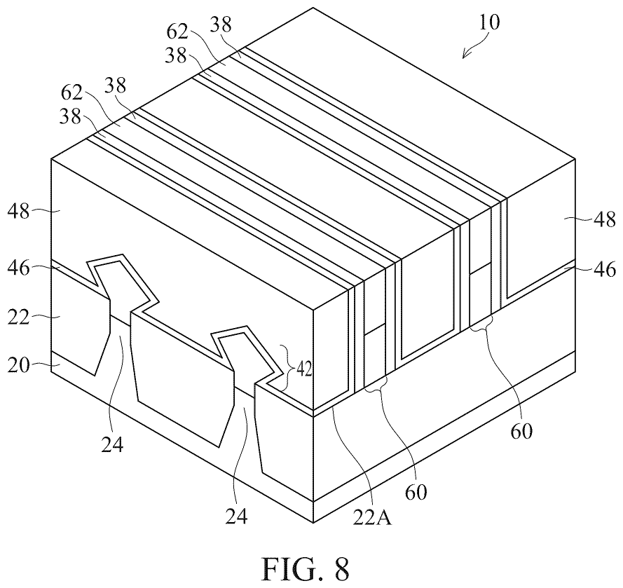

As shown in FIGS. 7 and 8, hard masks 62 may be formed over the gate stacks 60, in accordance with some embodiments. The formation of hard masks 62 may include recessing the gate stacks 60 through etching to form recesses, as shown in FIG. 7. The recesses may be formed using one or more suitable etching processes, such as a wet etching process and/or a dry etching process. The recesses may be filled with one or more dielectric materials, and a planarization process (e.g., a CMP or the like) may be performed. The remaining portions of the dielectric material form the hard masks 62, as shown in FIG. 8. The dielectric material(s) may be the same as or different from the materials of the BESL 46, the dielectric layer 48, and/or the gate spacers 38. In accordance with some embodiments, the hard masks 62 are formed of silicon nitride, silicon oxynitride, silicon oxycarbide, silicon carbonitride, silicon oxycarbonitride, the like, or a combination thereof.

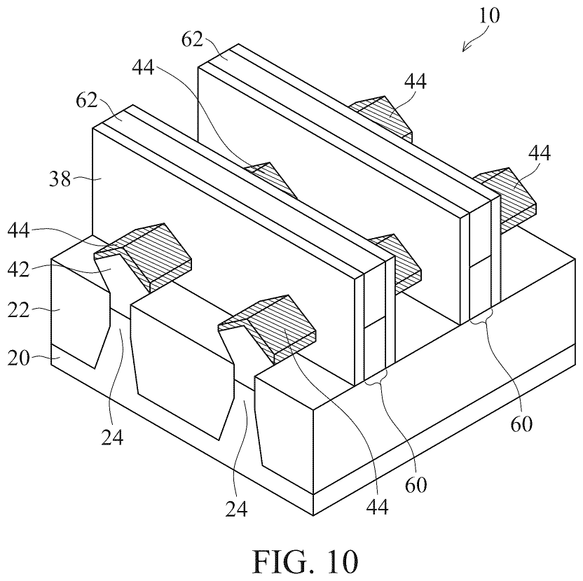

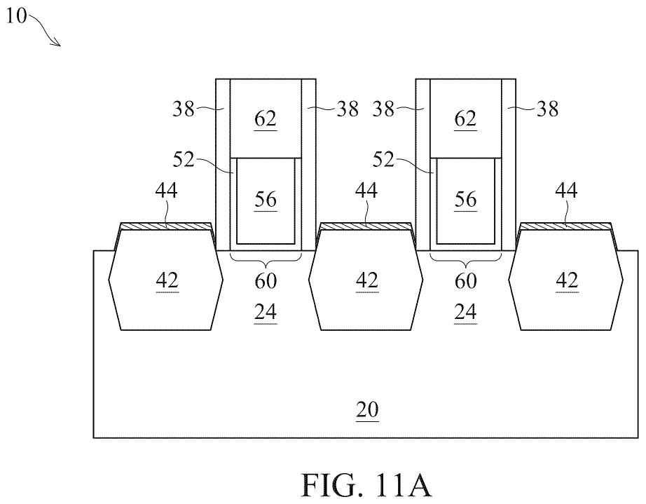

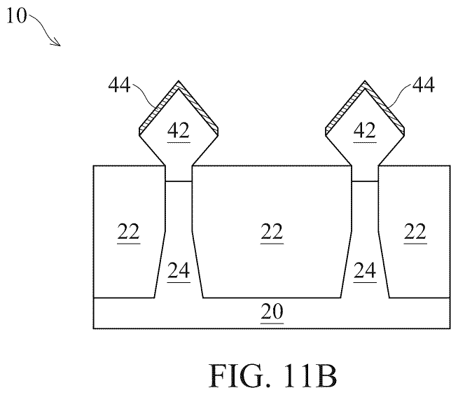

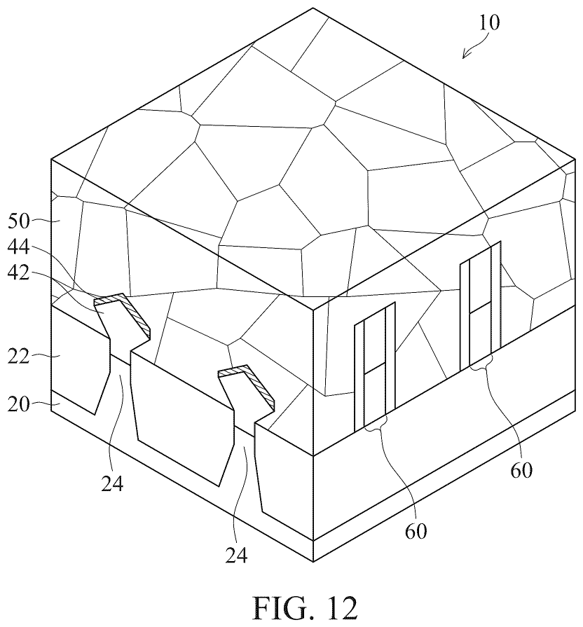

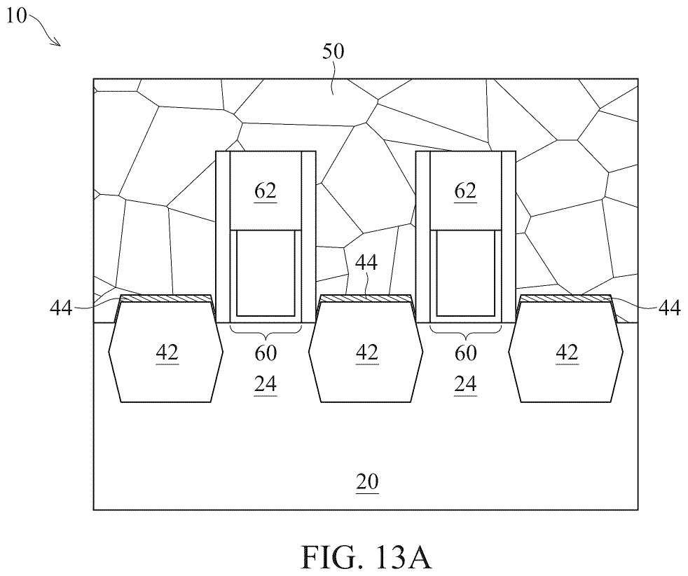

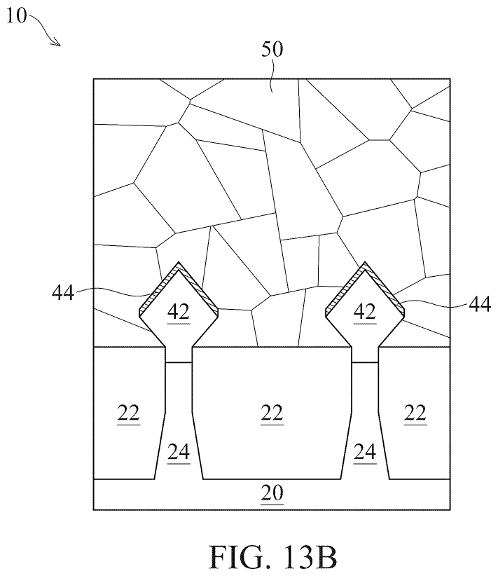

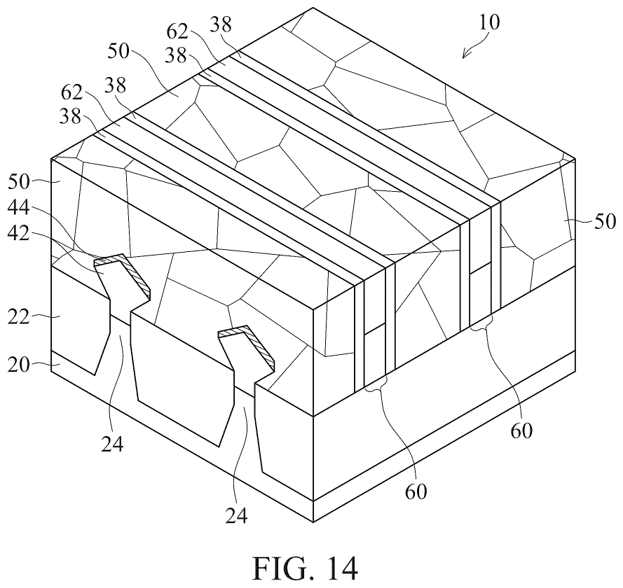

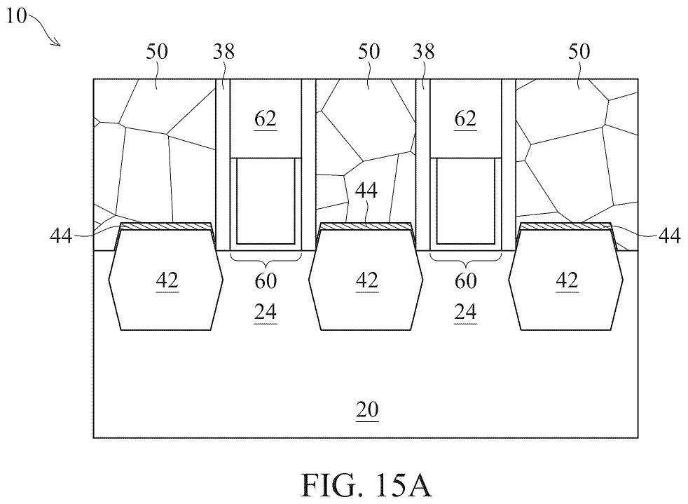

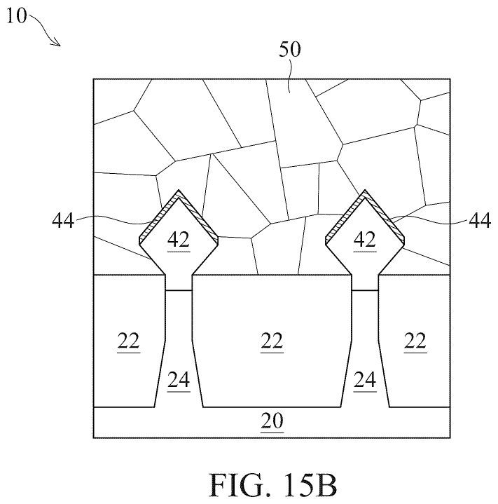

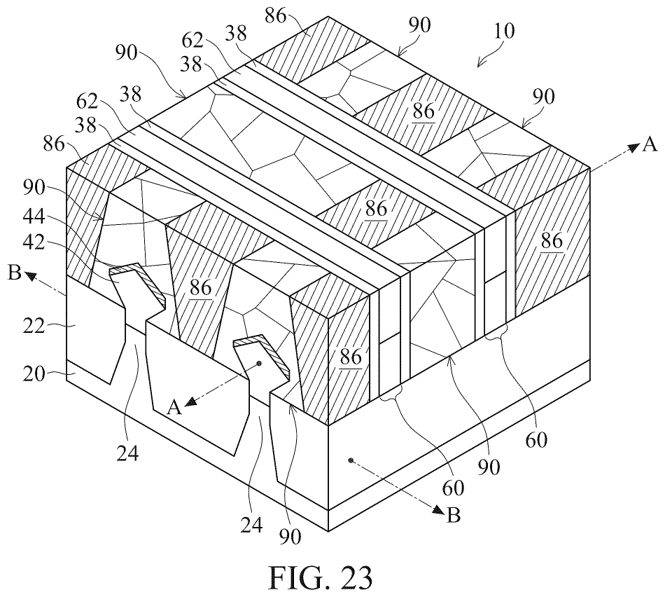

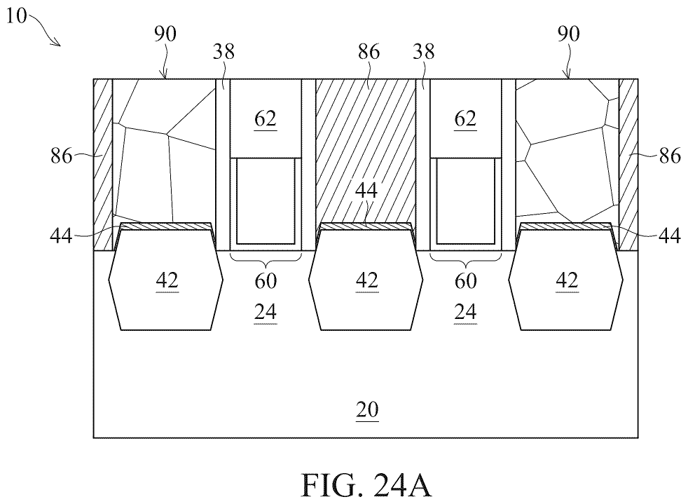

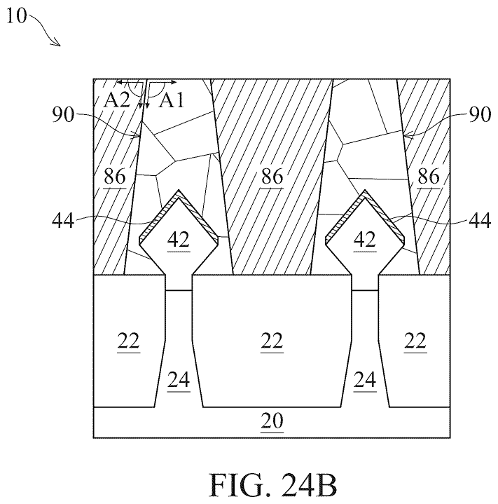

FIGS. 9 through 24B illustrate intermediate steps in the formation of source/drain contacts 90 (see FIGS. 23, 24A-24B), in accordance with some embodiments. FIGS. 9, 10, 12, 14, and 23 illustrate a perspective view. FIGS. 11A, 13A, 15A, 16A, 17A, 18A, 19A, 20A, 21A, 22A, and 24A illustrate cross-sectional views along the reference cross-section A-A shown in FIG. 9. FIGS. 11B, 13B, 15B, 16B, 17B, 18B, 19B, 20B, 21B, 22B, and 24B illustrate cross-sectional views along the reference cross-section B-B shown in FIG. 9. FIGS. 11A-11B are cross-sectional views corresponding to the structure shown in FIG. 10, FIGS. 13A-13B are cross-sectional views corresponding to the structure shown in FIG. 12, FIGS. 15A-15B are cross-sectional views corresponding to the structure shown in FIG. 14, and FIGS. 24A-24B are cross-sectional views corresponding to the structure shown in FIG. 23. As described below, in some embodiments the source/drain contacts 90 are formed by depositing a conductive material 50 (see FIGS. 12, 13A-13B) over the structure and then patterning the conductive material 50, with the source/drain contacts 90 comprising the remaining portions of the patterned conductive material 50.

In FIG. 9, the dielectric layer 48 and the BESL 46 are removed to expose the epitaxial source/drain regions 42 and the isolation regions 22, in accordance with some embodiments. The diectric layer 48 may be removed, for example, using a suitable wet etching process and/or dry etching process. The BESL 46 may be used as an etch stop during etching of the dielectric layer 48, and may removed in a separate etching step. Removing the dielectric layer 48 and the BESL 46 may expose top surfaces of the isolation regions 22, as shown in FIG. 9.

In FIGS. 10, 11A, and 11B, silicide regions 44 are formed on exposed surfaces of the epitaxial source/drain regions 42, in accordance with some embodiments. In some embodiments, the silicide regions 44 are formed by depositing a metal material on surfaces of the epitaxial source/drain regions 42 and then performing a thermal anneal process to react the metal material with the semiconductor material of the epitaxial source/drain regions 42. The metal material may include, for example, nickel, cobalt, titanium, tantalum, platinum, tungsten, other noble metals, other refractory metals, rare earth metals or their alloys, the like, or combinations thereof. In some embodiments, un-reacted portions of the metal material (e.g., on the fins 24) are subsequently removed (e.g., using an etching process). The silicide regions 44 may comprise germanide regions and/or silicon-germanide regions in addition to silicide regions or instead of silicide regions, in some embodiments. The silicide regions 44 are shown as being formed on the upper surfaces of the epitaxial source/drain regions 42, but in other embodiments the silicide regions 44 may also be formed on other surfaces of the epitaxial source/drain regions 42, such as on underside surfaces of the epitaxtial source/drain regions 42.

In FIGS. 12, 13A, and 13B, a conductive material 50 is deposited over the structure. The conductive material 50 covers the epitaxial source/drain regions 42 and is subsequently patterned to form source/drain contacts 90 (see FIGS. 23, 24A-24B), in accordance with some embodiments. The conductive material 50 may comprise an optional liner and a metal fill material, which are not separately illustrated in the figures. The liner may be, for example, a diffusion barrier layer, an adhesion layer, or the like, and may comprise materials such as titanium, titanium nitride, tantalum, tantalum nitride, cobalt, the like, or a combination thereof.

The metal fill material is deposited over the liner (if present), and may cover and extend over the epitaxial source/drain regions 42, the gate spacers 38, and the gate stacks 60, in some embodiments. The metal fill material may include, for example, copper, a copper alloy, silver, gold, tungsten, cobalt, aluminum, nickel, ruthenium, the like, or a combination thereof. The metal fill material and the liner may be deposited by any suitable techniques, such as CVD, PECVD, PVD, ALD, plasma-enhanced ALD (PEALD), electrochemical plating (ECP), electroless plating, or the like. Other materials or deposition techniques are possible. In some embodiments, the conductive material 50 may be deposited to a thickness in the range of about 50 nm to about 150 nm, though other thicknesses are possible. In some embodiments, an anneal process is performed after depositing the conductive material 50. The anneal process may be performed for between about 3 minutes and about 15 minutes, and may include a process temperature in the range of about 250° C. to about 400° C. Other anneal process parameters are possible.

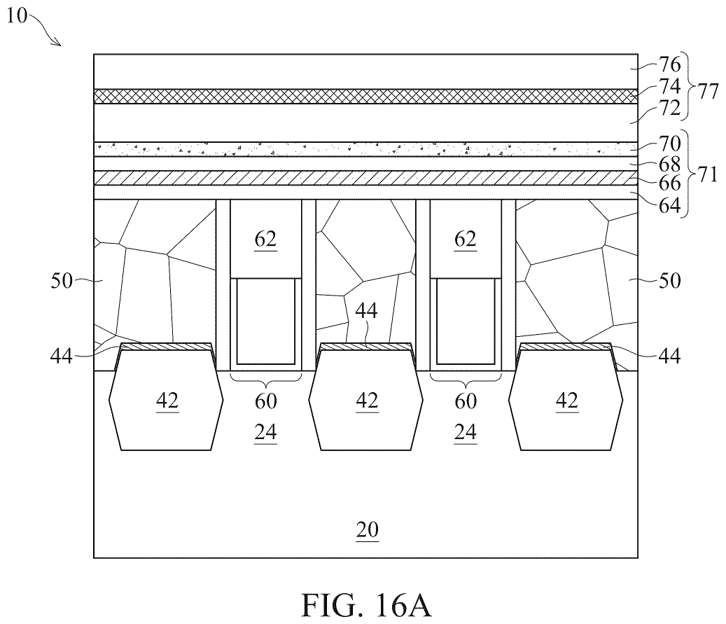

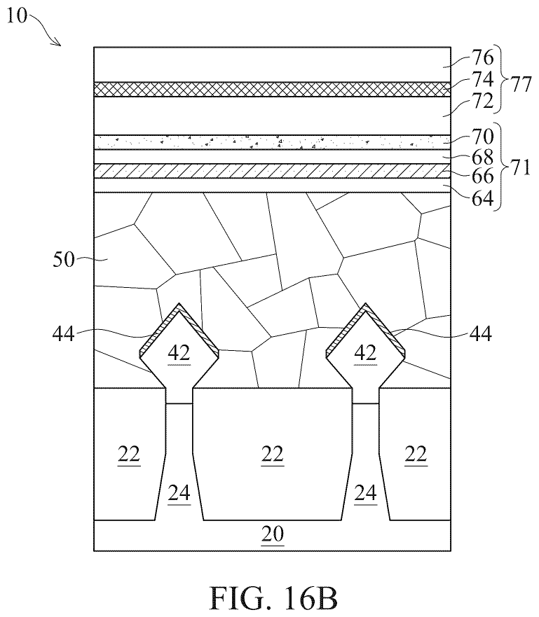

In some cases, the size of the grains formed in a deposited metal may depend on the dimensions of the region into which the metal is deposited. For example, a metal deposited into a more confined region (e.g., into a narrow trench) may form smaller grains than the metal deposited into a less confined region (e.g., into a wide trench or over an open region). Accordingly, by depositing the metal fill material of the conductive material 50 over an open region of the structure (e.g., as shown in FIG. 12), the metal fill material may be formed having larger metal grains than, for example, by depositing the metal fill material into trenches. As described below in FIGS. 16A through 24B, source/drain contacts 90 may be formed by patterning the conductive material 50 that has been deposited over an open region of the structure (e.g., as shown in FIG. 12). In this manner, source/drain contacts 90 formed by depositing a conductive material 50 over the epitaxial source/drain regions 42 and then patterning the conductive material 50 as described herein may have larger metal grains than, for example, source/drain contacts formed by forming trenches over epitaxial source/drain regions and then depositing conductive material into the trenches. In some embodiments, a conductive material 50 (e.g., copper) deposited over an open region as described herein may have metal grains with an average size in the range of about 50 nm to about 200 nm, though other sizes are possible. In some cases, a conductive material 50 deposited over an open region as described herein may have metal grains that are between about 200 nm and about 600 nm larger than the metal grains of a conductive material deposited into trenches. Other sizes or relative sizes are possible, and other conductive materials 50 than copper may similarly form larger grains in open areas than in trenches.

While relative terms such as “larger” or “smaller” have been used to compare the sizes of grains, one of ordinary skill in the art would understand that grains having a range of sizes and shapes may be formed within a deposited metal, and these relative terms may be used to compare different distributions comprising a plurality of grain sizes. For example, the relative terms may compare characteristics such as average grain size, median grain size, the largest and/or smallest grain size within a range of grain sizes, or other characteristics or statistical measurements. In some cases, the term “grain size” may refer to a dimension of a grain (e.g., length, width, etc.), the volume of a grain, or the like.

In some cases, a metal formed having larger grains may have less resistance than the same metal formed having smaller grains. For example, a metal having larger grains has a smaller total number of grains, and thus may have a smaller density of grain boundaries. Accordingly, resistive effects due to electron scattering at grain boundaries may be reduced for the metal having larger grains. In this manner, source/drain contacts 90 formed having larger metal grains as described herein may have less resistance (e.g., contact resistance) than source/drain contacts formed having smaller metal grains. In some cases, forming source/drain contacts 90 having larger metal grains as described herein may reduce the contact resistance of source/drain contacts 90 by between about 80% and about 98%, though other percentages are possible. In some cases, reducing the resistance of source/drain contacts by forming larger metal grains as described herein can improve efficiency, improve speed, or reduce resistive heating of a device.

In FIGS. 14, 15A, and 15B, a planarization process is performed to remove excess portions of the conductive material 50, in accordance with some embodiments. The planarization process may include, for example, a CMP process, a grinding process, an etching process, the like, or a combination thereof. In some embodiments, after performing the planarization process, top surfaces of the conductive material 50, the gate spacers 38, and/or the hard masks 62 may be level.

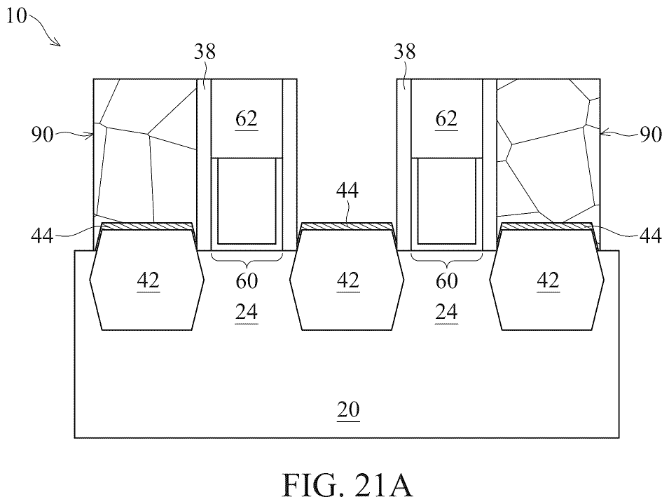

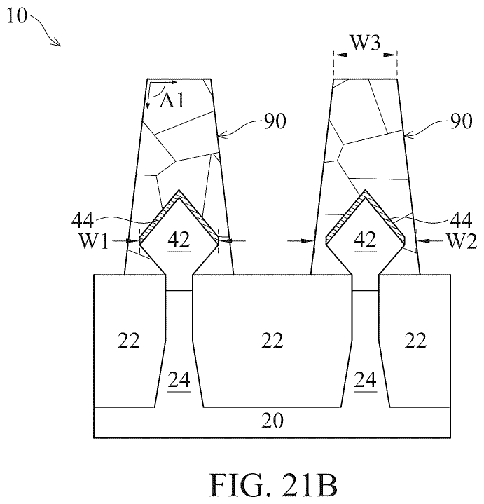

FIGS. 16A through 21B illustrate intermediate steps in the patterning of the conductive material 50 to form source/drain contacts 90 (see FIGS. 21A-21B), in accordance with some embodiments. For example, forming the source/drain contacts 90 may include forming mask layers 71 (see FIGS. 16A-16B) over the conductive material 50, patterning the mask layers 71, and then using the patterned mask layers 71 as an etching mask for patterning the conductive material 50. The remaining portions of the patterned conductive material 50 form the source/drain contacts 90.

In FIGS. 16A and 16B, mask layers 71 and a first photoresist structure 77 are formed over the conductive material 50, the hard masks 62, and the gate spacers 38, in accordance with some embodiments. In some embodiments, the mask layers 71 comprise a first dielectric layer 64, a hard mask layer 66, a second dielectric layer 68, and a patterning layer 70. The mask layers 71 may comprise more or fewer layers in other embodiments.

The first dielectric layer 64 of the mask layers 71 is deposited over the conductive material 50, the hard masks 62, and the gate spacers 38. In some embodiments, the first dielectric layer 64 is formed of a material similar to those described previously for the dielectric layer 48 (see FIG. 5) and may be formed using similar techniques as those described previously for the dielectric layer 48. For example, the first dielectric layer 64 may comprise silicon oxide, PSG, BSG, BPSG, USG, the like, or a combination thereof. Other materials or deposition techniques are possible. The hard mask layer 66 is formed over the first dielectric layer 64 and may be a material such as titanium, titanium nitride, tantalum, tantalum nitride, silicon nitride, boron nitride, silicon carbide, tungsten carbide, the like, or a combination thereof. The hard mask layer 66 may be formed using a suitable technique, such as CVD, PECVD, PVD, ALD, the like, or a combination thereof. Other materials or deposition techniques are possible. The second dielectric layer 68 is formed over the hard mask layer 66 and may be formed using materials or techniques similar to those described previously for the dielectric layer 48. For example, the second dielectric layer 68 may be an oxide such as silicon oxide, titanium oxide, or the like. Other materials or deposition techniques are possible. In some embodiments, the first dielectric layer 64 and the second dielectric layer 68 are the same material, though the first dielectric layer 64 and the second dielectric layer 68 may be different materials in other embodiments. The patterning layer 70 is formed over the second dielectric layer 68. In some embodiments, the patterning layer 70 comprises a material such as silicon, amorphous silicon, silicon oxide, silicon nitride, the like, or a combination thereof. The patterning layer 70 may be formed using a suitable technique, such as CVD, PECVD, PVD, ALD, the like, or a combination thereof. Other materials or deposition techniques are possible.

Still referring to FIGS. 16A-16B, the first photoresist structure 77 is formed over the mask layers 71, in accordance with some embodiments. The first photoresist structure 77 may be any acceptable photoresist structure, such as a single-layer photoresist, a bi-layer photoresist, a tri-layer photoresist, or the like. In the illustrated embodiment, the first photoresist structure 77 is a tri-layer photoresist including a bottom layer 72, a middle layer 74, and a top layer 76. In some embodiments, the bottom layer 72 may be a material such as amorphous carbon, CₓH_{y}O_{z}, or the like, which may be formed using a spin-on process or another suitable deposition technique. Other materials are possible. The middle layer 74 may comprise an oxide (e.g., silicon oxide or the like), a nitride (e.g., silicon nitride or the like), an oxynitride (e.g. silicon oxynitride or the like), the like, or a combination thereof. The middle layer 74 may be formed using a suitable technique, such as CVD, PVD, ALD, the like, or a combination thereof. In some embodiments, the middle layer 74 is an Anti-Reflective Coating (ARC) layer. The top layer 76 may be, for example, a photoresist or other photosensitive material, which may be formed using a spin-on process or another suitable deposition technique. Other materials are possible.

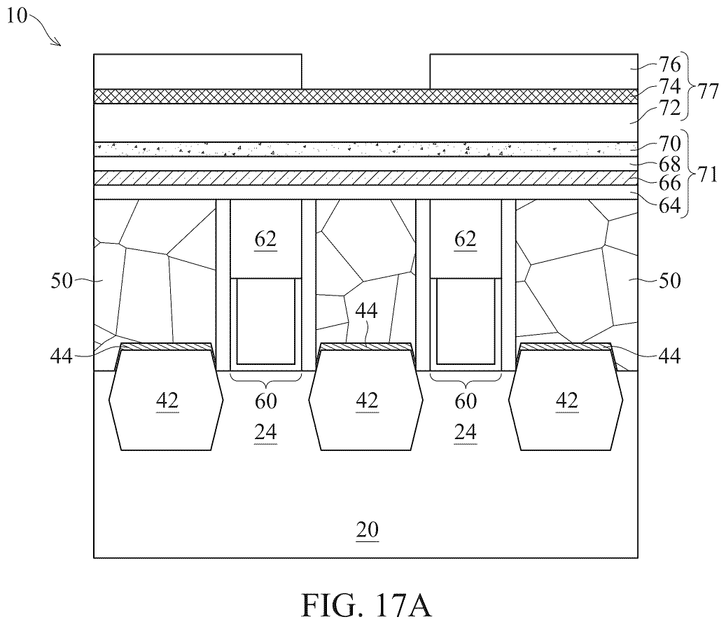

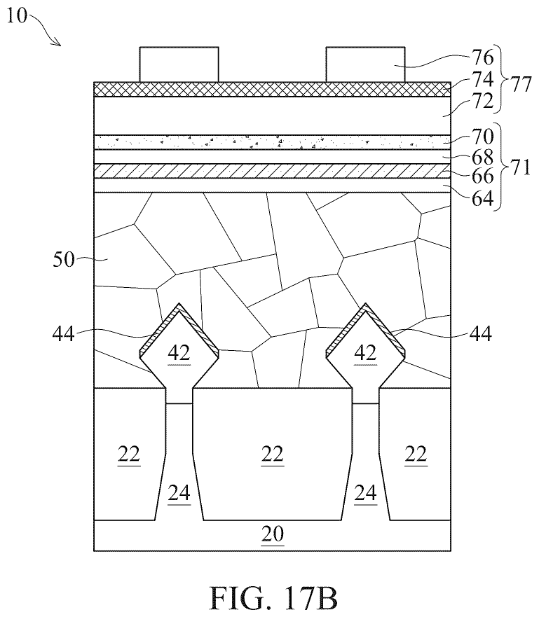

In FIGS. 17A and 17B, the top layer 76 of the first photoresist structure 77 is patterned, in accordance with some embodiments. The top layer 76 may be patterned using suitable photolithographic techniques. In the embodiment shown in FIGS. 17A-17B, the regions where the top layer 76 has been removed correspond to regions of the conductive material 50 that are subsequently removed. In this manner, the patterned top layer 76 can define regions of the conductive material 50 that are subsequently removed to form “cuts” that separate adjacent source/drain contacts 90.

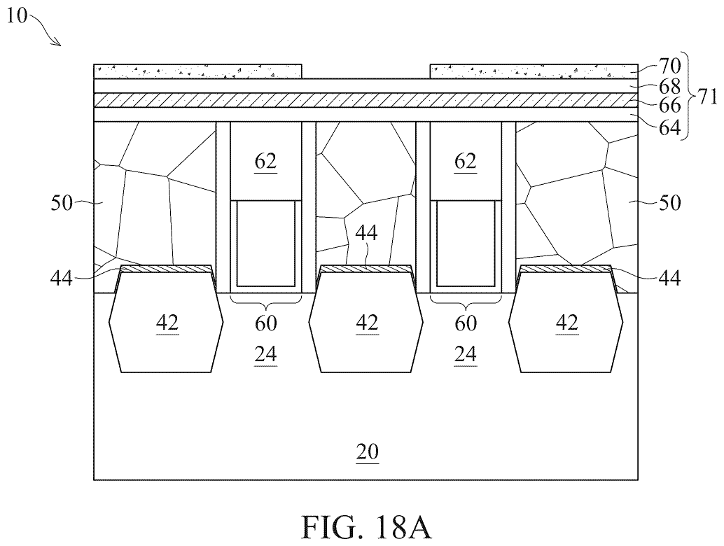

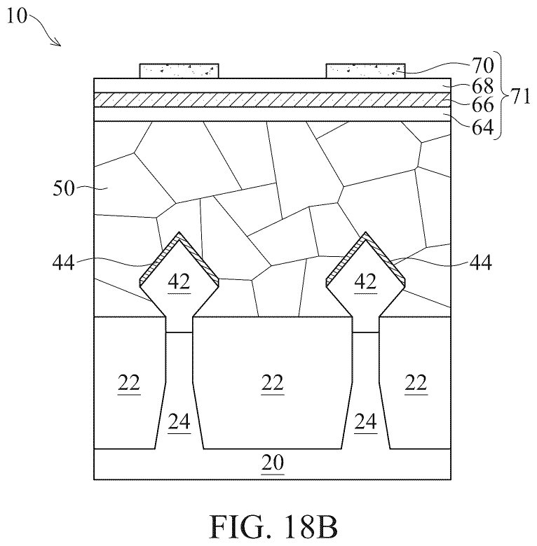

In FIGS. 18A and 18B, the patterning layer 70 is patterned using the patterned top layer 76 as an etching mask, in accordance with some embodiments. For example, one or more etching processes may be used to extend the pattern of the patterned top layer 76 through the middle layer 74 and the bottom layer 72 and into the patterning layer 70. The etching processes may include, for example, wet etching processes and/or dry etching processes, or may include anisotropic etching processes. Portions of the bottom layer 72, the middle layer 74, and/or the top layer 74 may remain on the patterning layer 70 after the etching processes, in some embodiments. In other embodiments, remaining portions of the bottom layer 72, the middle layer 74, and/or the top layer 74 may be removed after the etching processes using, for example, an ashing process or other suitable process.

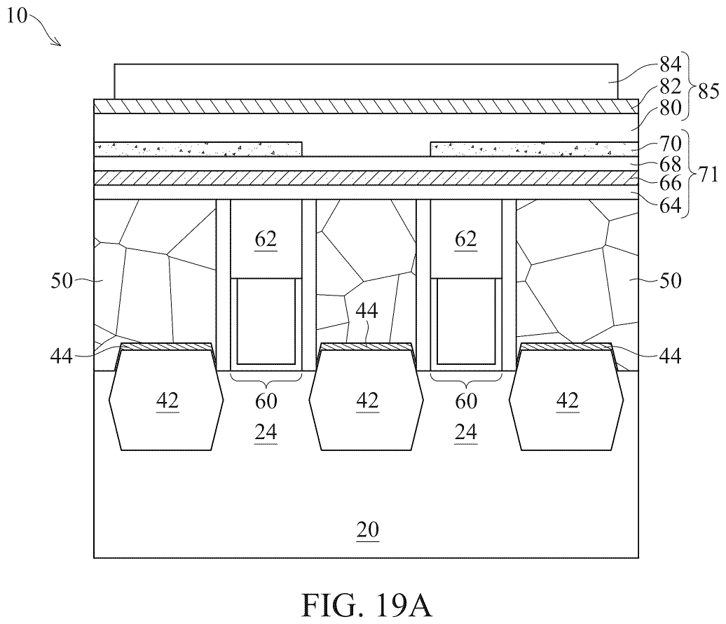

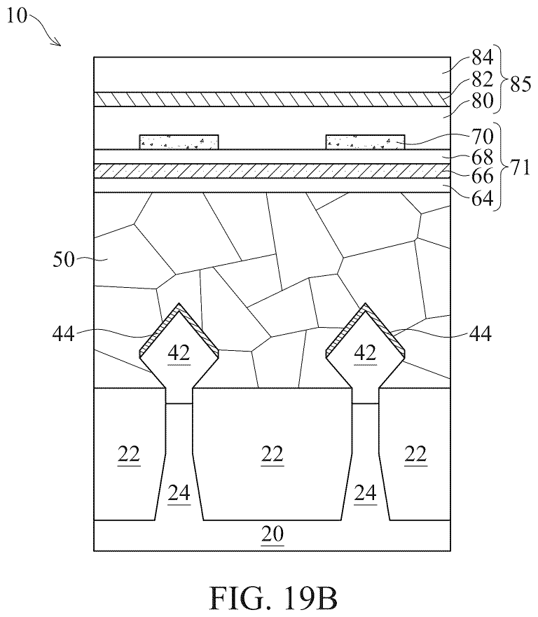

In FIGS. 19A and 19B, a second photoresist structure 85 is formed over the mask layers 71 and patterned, in accordance with some embodiments. The second photoresist structure 85 may be similar to the first photoresist structure 77 described previously, and may be formed in a similar manner. For example, the second photoresist structure 85 may be a tri-layer photoresist including a bottom layer 80, a middle layer 82, and a top layer 84. The second photoresist structure 85 may have a different number of layers in other embodiments. In FIGS. 19A-19B, the top layer 84 of the second photoresist structure 85 has been patterned, in accordance with some embodiments. The top layer 84 may be patterned using suitable photolithography techniques. In the embodiment shown in FIGS. 19A-19B, the regions where the top layer 84 has been removed correspond to additional regions of the conductive material 50 that are subsequently removed. As a non-limiting example, the remaining portions of the patterned top layer 76 can define larger regions of the structure within which source/drain contacts 90 may be formed.

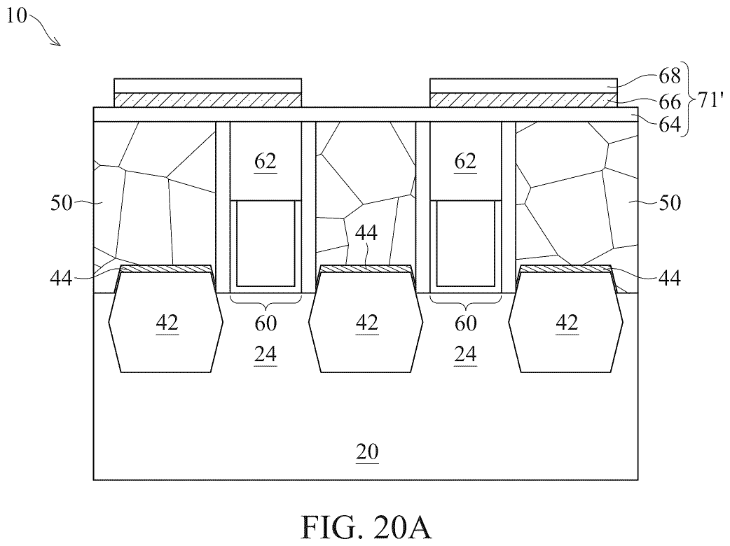

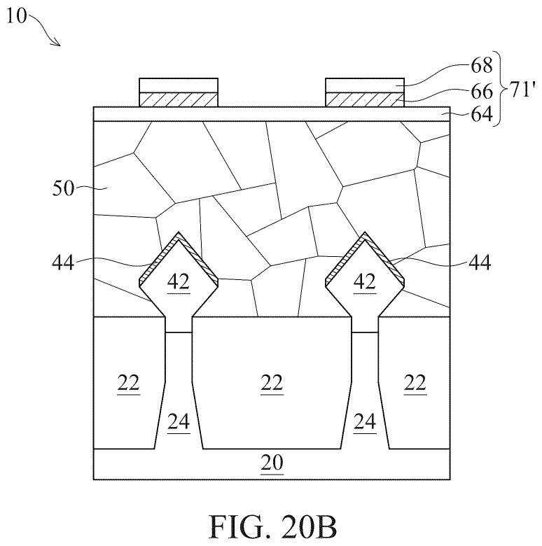

In FIGS. 20A and 20B, the hard mask layer 66 and the second dielectric layer 68 are patterned to form an etching mask 71′, in accordance with some embodiments. The etching mask 71′ used during the subsequent etching of the conductive material 50 (see FIGS. 21A-21B). The hard mask layer 66 and the second dielectric layer 68 may be patterned using the second photoresist structure 85 and the patterning layer 70 as an etching mask, in some embodiments. For example, the pattern of the top layer 84 described for FIGS. 19A-19B may be extended through the middle layer 82 and the bottom layer 80 to the patterning layer 70 using one or more etching processes. Then, the patterning layer 70 may be used as an etching mask to pattern the the hard mask layer 66 and the second dielectric layer 68 using one or more etching processes, forming the etching mask 71′. The etching processes may include, for example, wet etching processes and/or dry etching processes, or may include anisotropic etching processes. Portions of the bottom layer 80, the middle layer 82, the top layer 84, and/or the patterning layer 70 may remain after the etching processes, in some embodiments. In other embodiments, remaining portions of the patterned bottom layer 72, the patterned middle layer 74, and/or the patterned top layer 70 may be removed after the etching processes using, for example, an ashing process or other suitable processes. In other embodiments, only the second dielectric layer 68 is patterned or the first dielectric layer 64 is also patterned when forming the etching mask 71′.

The patterning process shown in FIGS. 16A through 20B is an illustrative example, and other patterning steps are possible. For example, another number or combination of photoresist structures may be used, another number or combination of mask layers may be used, or another number or combination of etching steps may be used. As an example, in the embodiment shown in FIGS. 16A-20B, the pattern defining the “cuts” of the source/drain regions 90 (in FIGS. 16A-18B) is formed before the pattern defining the larger regions of source/drain contacts 90 (in FIGS. 19A-19B), but in other embodiments, the pattern defining the larger regions of source/drain contacts 90 may be formed before the pattern defining the “cuts” of the source/drain regions 90. These and other variations of forming an etching mask for the conductive material 50 are possible, and all such variations are within the scope of the present disclosure.

In FIGS. 21A and 21B, the conductive material 50 is patterned using the etching mask 71′ to form source/drain contacts 90, in accordance with some embodiments. For example, the pattern of the hard mask layer 66 and the second dielectric layer 68 (see FIGS. 20A-20B) may be extended through the first dielectric layer 64 and into the conductive material 50 using one or more etching processes The etching processes may include, for example, wet etching processes and/or dry etching processes, or may include anisotropic etching processes. The dry etching processes may include, for example, a Reactive Ion Etch (RIE) process or the like, which may include process gases such as CF₄, C₄F₆, C₄F₈, Cl₂, BCl₃, O₂, CO, CO₂, the like, or a combination thereof. Other etching processes or process gases are possible. After etching the conductive material 50, portions of the etching mask 71′ may remain on the conductive material 50, in some cases. Remaining portions of the etching mask 71′ may be removed using, for example, a suitable etching process.

The source/drain contacts 90 physically and electrically contact the epitaxial source/drain regions 42. The source/drain contacts 90 may extend along upper surfaces, side surfaces, and/or underside surfaces of the epitaxial source/drain regions 42. For example, in some embodiments, the source/drain contacts 90 may cover upper surfaces, side surfaces, and underside surfaces of the epitaxial source/drain regions 42, as shown in FIG. 21B. The source/drain contacts 90 may physically contact silicide regions 44 and/or surfaces of the epitaxial source/drain regions 42. In some cases, increasing the contact area between a source/drain contact 90 and an epitaxial source/drain region 42 can reduce contact resistance. In this manner, by forming source/drain contacts 90 that extend on side surfaces and/or underside surfaces of the epitaxial source/drain regions 42 as described herein, the contact resistance of the source/drain contacts 90 may be reduced, which can improve device performance. In some cases, this reduction in resistance due to increased contact area may be in addition to a reduction in resistance due to the formation of larger metal grains, as described previously. For example, in some embodiments, the source/drain contacts 90 may be formed contacting all of the exposed area of the source/drain contacts 42 (e.g., as shown in FIGS. 10-11B), though other contact areas are possible. In some cases, by depositing the conductive material 50 first and then patterning it to form the source/drain regions 90 as described herein, damage to the epitaxial source/drain regions 42 from etching may be reduced.

In some embodiments, a source/drain contact 90 may have a width W2 that is greater than a width W1 of a epitaxial source/drain region 42, as shown in FIG. 21B. In some embodiments, forming the source/drain contacts 90 such that the width W2 is greater than the width W1 of the epitaxial source/drain regions 42 may allow the source/drain contacts 90 to be formed with increased contact area, as described above. In other embodiments, a source/drain contact 90 may have a width W2 that is about the same as or smaller than the width W1 of a epitaxial source/drain region 42.

The source/drain contacts 90 may have straight sidewalls, as shown in FIGS. 21A-21B, or may have concave sidewalls, convex sidewalls, or irregular sidewalls. The source/drain contacts 90 may have vertical sidewalls, may have sloped sidewalls, or may have tapered sidewalls as shown in FIG. 21B. For example, in some embodiments, a source/drain contact 90 may have a width W3 near the top of the source/drain contact 90 that is smaller than a width near the bottom of the source/drain contact 90 (e.g., width W2). In some embodiments, the sidewalls of a source/drain contact may be separated by a larger distance near the bottom of the sidewalls than near the top of the sidewalls. In other embodiments, a source/drain contact 90 may have a width W3 near the top of the source/drain contact 90 that is about the same as a width near the bottom of the source/drain contact 90 (e.g., width W2). In some embodiments, an angle A1 of a sidewall of a source/drain contact 90 with respect to a top surface of the source/drain contact 90 may in the range of about 90° to about 95°, though other angles are possible. In some embodiments, the width near the top of a source/drain contact 90 (e.g., width W3) may be between about 105% and about 130% of the width near the bottom of the source/drain contact 90 (e.g., width W2). In some embodiments, the angle A1 or the width W2 may be controlled by controlling the directionality or other parameters of the etching processes.

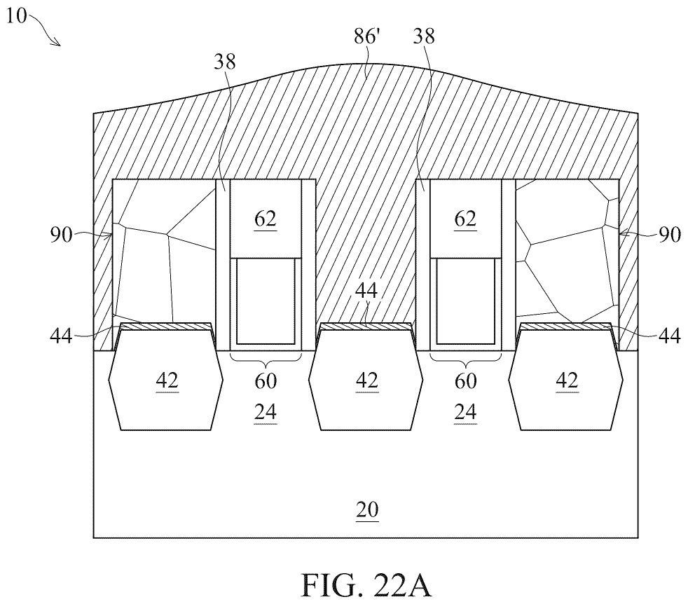

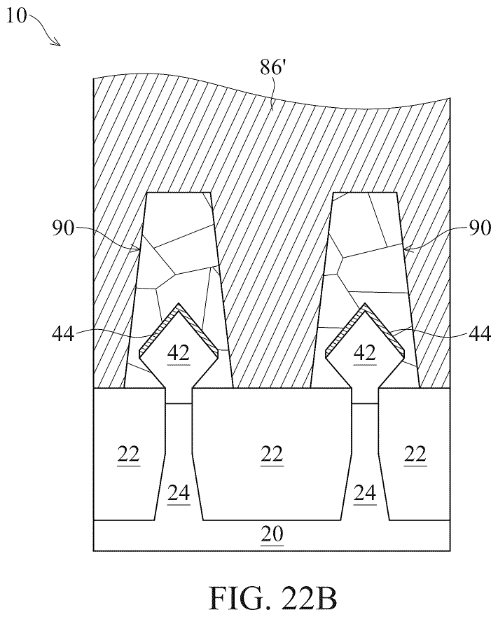

In FIGS. 22A and 22B, a first ILD material 86′ is deposited over the structure, in accordance with some embodiments. The first ILD material 86′ may be a material similar to those described previously for the dielectric layer 48, and may be formed in a similar manner. Other materials or deposition techniques are possible. As shown in FIGS. 22A-22B, the first ILD material 86′ may fill the regions between source/drain contacts 90 (e.g., the regions for “cuts” or the like) to isolate the source/drain contacts 90.

In FIGS. 23, 24A, and 24B, a planarization process is performed to remove excess first ILD material 86′, in accordance with some embodiments. After performing the planarization process, the remaining regions of first ILD material 86′ form the first ILD 86. The planarization process may include, for example, a CMP process, a grinding process, and etching process, the like, or a combination thereof. In some embodiments, the planarization process exposes top surfaces of the source/drain contacts 90, the first ILD 86, the hard mask 62, and the gate spacers 38, which may be level. In some embodiments, after performing the planarization process, a sidewall of the first ILD 86 adjacent a source/drain contact 90 may have an angle A2 with respect to the top surface of the first ILD 86 that is in the range of about 85° to about 90°, though other angles are possible.

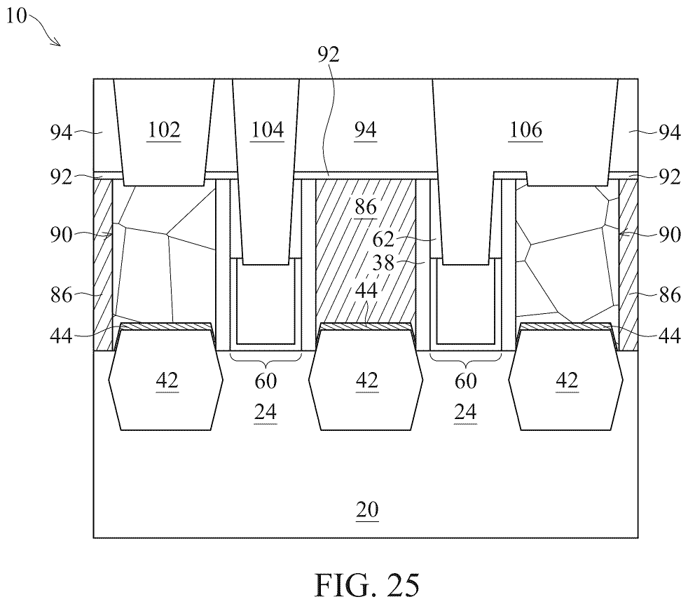

FIG. 25 illustrates the formation of source/drain contacts 102, gate contacts 104, and hybrid contacts 106, in accordance with some embodiments. FIG. 25 illustrates a cross-sectional view along reference cross-section A-A (see FIG. 23). The source/drain contacts 102 may physically and electrically couple the source/drain contacts 90, the gate contacts 104 may physically and electrically couple the gate stacks 60, and the hybrid contacts 106 may physically and electrically couple both source/drain contacts 90 and gate stacks 60. In some embodiments, a second ILD 94 is deposited over the first ILD 86, the source/drain contacts 90, and the hard masks 62. The second ILD 94 may be formed of a material similar to those described for the first ILD 86, and may be formed using similar techniques. An optional etch stop layer (ESL) 92 may be formed between the first ILD 86 and the second ILD 94, in some embodiments. In some embodiments the ESL 92 may comprise silicon nitride, silicon oxynitride, silicon oxide, or the like and may be deposited using CVD, PVD, ALD, or the like. Other materials or deposition techniques are possible.

As illustrated FIG. 25, the source/drain contacts 102, the gate contacts 104, and the hybrid contacts 106 are formed extending through the second ILD 94 and the ESL 92, in accordance with some embodiments. As an example of formation, openings for the source/drain contacts 102 may be formed through the second ILD 94 and the ESL 92 to expose the source/drain contacts 90, and openings for the gate contacts 104 may be formed through the second ILD 94 and the hard masks 62 to expose the gate stacks 60. The openings may be formed using acceptable photolithography and etching techniques. A liner (not shown), such as a diffusion barrier layer, an adhesion layer, or the like, and a conductive material may then be formed in the openings. The liner may comprise titanium, titanium nitride, tantalum, tantalum nitride, or the like. The conductive material may be copper, a copper alloy, silver, gold, tungsten, cobalt, aluminum, nickel, the like, or a combination thereof. Other materials are possible. A planarization process, such as a CMP process, may be performed to remove excess material from a surface of the second ILD 94. The remaining liner and conductive material form the source/drain contacts 102 and gate contacts 104 in the openings. The hybrid contacts 106 may be formed in a similar manner as the source/drain contacts 102 and the gate contacts 104. The source/drain contacts 102, the gate contacts 104, and/or the hybrid contacts 106 may be formed in different processes, or may be formed in the same process(es). Other formation techniques are possible. Although shown as being formed in the same cross-sections, it should be appreciated that source/drain contacts 102, gate contacts 104, and/or hybrid contacts 106 may be formed in different cross-sections, which may avoid shorting of the contacts.

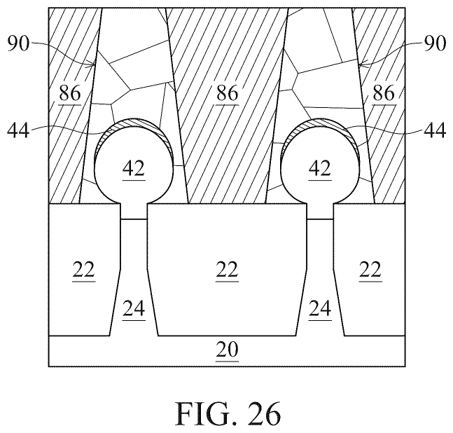

FIGS. 26 through 31C illustrate embodiments of epitaxial source/drains 42 and source/drain contacts 90. FIGS. 26 through 31C are illustrated along the reference cross-section B-B (see FIG. 23). The epitaxital source/drain regions 42 and source/drain contacts 90 shown in FIGS. 26-31C may be similar to the epitaxital source/drain regions 42 and source/drain contacts 90 described previously, and may be formed using similar techniques. For example, the source/drain contacts 90 described for FIGS. 26-31C may be formed by depositing a conductive material 50 and then patterning it. In this manner, the source/drain contacts 90 described for FIGS. 26-31C may be formed having larger metal grains and/or an increased contact area. The embodiments shown in FIGS. 26-31C are non-limiting examples, and other variations, combinations, or configurations are possible and considered within the scope of the present disclosure.

In some embodiments, the epitaxial source/drain regions 42 may have a different shape than shown in FIGS. 4-25. For example, FIG. 26 illustrates an embodiment in which the epitaxial source/drain regions 42 have a rounded shape rather than the faceted shape shown in FIGS. 4-25. In some cases, epitaxial source/drain regions 42 comprising different materials or dopants may have different shapes, or epitaxial source/drain regions 42 formed using different processes or parameters may have different shapes. For example, in some embodiments, a p-type epitaxial source/drain region 42 may have a more faceted shape similar to those shown in FIGS. 4-25 and an n-type epitaxial source/drain region may have a more rounded shape similar to those shown in FIG. 26. Other shapes, variations, or configurations are possible.

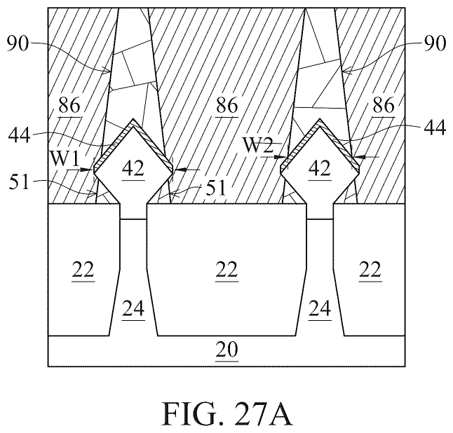

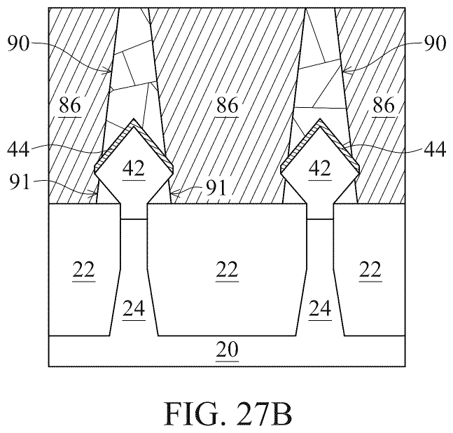

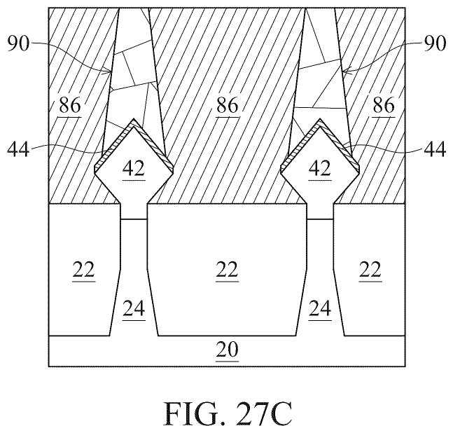

FIGS. 27A, 27B, and 27C show embodiments in which a width W1 of the epitaxial source/drain regions 42 is larger than a width W2 of the source/drain contacts 90. The size of the width W2 may be controlled, for example, by controlling the size of the pattern features of the etching mask 71′ (see FIGS. 20A-20B). As shown in FIGS. 27A-27C, the source/drain contacts 90 may partially cover upper surfaces of the epitaxial source/drain regions 42 such that portions of upper surfaces of the epitaxial source/drain regions 42 are free of the source/drain contacts 90. In some embodiments, side surfaces of the epitaxial source/drain regions 42 may physically contact the first ILD 86 or may protrude into the first ILD 86, as shown in FIGS. 27A-27C.

Referring to FIG. 27A, bottom regions 51 of the conductive material 50 may be present underneath the epitaxial source/drain regions 42, in some embodiments. For example, bottom regions 51 may be present between the isolation regions 22 and underside surfaces of the epitaxial source/drain regions 42. The bottom regions 51 may be larger or smaller than shown in FIG. 27A, or may have a different shape than shown in FIG. 27A. In some cases, the bottom regions 51 are separated from the source/drain contacts 90 by the epitaxial source/drain regions 42.

FIG. 27B illustrates an embodiment similar to FIG. 27A, except that air gaps 91 are formed between the isolation regions 22 and the epitaxial source/drain regions 42. In some cases, both air gaps 91 and bottom regions 51 may be present between the isolation regions 22 and the epitaxial source/drain regions 42. The air gaps 91 may be larger or smaller than shown in FIG. 27B, or may have a different shape than shown in FIG. 27B. The air gaps 91 may be formed, for example, by overetching the conductive material 50 (see FIGS. 21A-21B) to remove conductive material 50 from regions underneath the epitaxial source/drain regions 42, and then incompletely filling the regions underneath the epitaxial source/drain regions 42 with the first ILD material 86′ (see FIGS. 22A-22B). FIG. 27C illustrates an embodiment similar to FIG. 27B, except that the regions underneath the epitaxial source/drain regions 42 are completely filled with the first ILD material 86′. In some embodiments, the underside surfaces of the epitaxial source/drain regions 42 may be free of conductive material 50, as shown in FIGS. 27B and 27C.

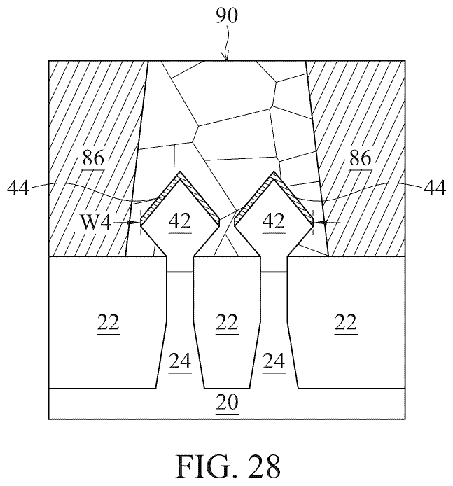

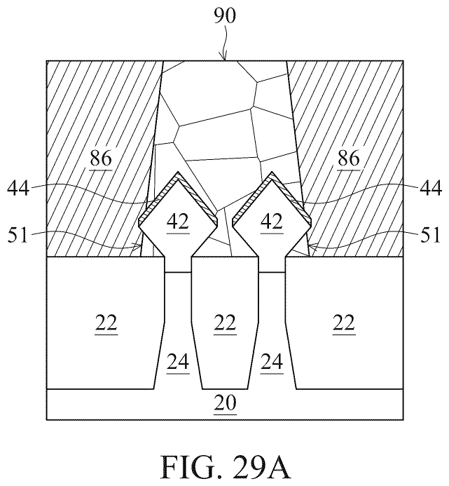

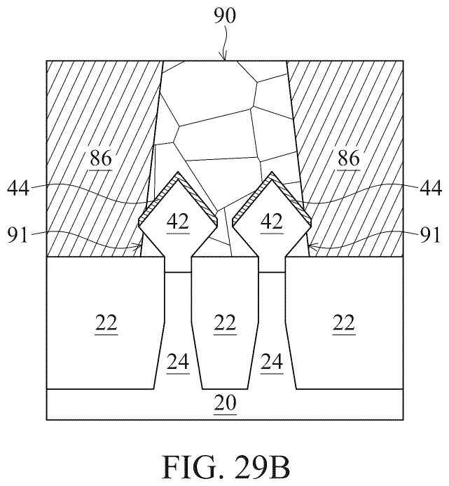

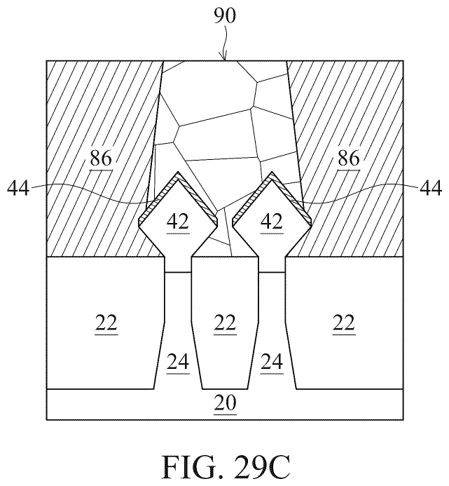

FIGS. 28, 29A, 29B, and 29C illustrate embodiments in which a single source/drain contact 90 is formed over multiple epitaxial source/drain regions 42. For example, FIGS. 28-29C each show a single source/drain contact 90 that is physically and electrically connected to two epitaxial source/drain regions 42, though a single source/drain region 90 may be connected to more than two epitaxial source/drain regions 42 in other embodiments. Turning to FIG. 28, an embodiment is shown for which the source/drain contact 90 has a width that is greater than the overall width W4 of the collection of epitaxial source/drain regions 42. As shown in FIG. 28, the overall width W4 may be, for example, the lateral distance between the outermost side surfaces (e.g., the outermost sidewalls) of the multiple epitaxial source/drain regions 42. In some embodiments, the conductive material 50 of the source/drain contact 90 may extend between each of the epitaxial source/drain regions 42 and may extend underneath each of the epitaxial source/drain regions 42.

FIGS. 29A-29C show embodiments in which the overall width W4 of the multiple epitaxial source/drain regions 42 is larger than a width of the single source/drain contact 90. In some embodiments, the single source/drain contact 90 may partially cover upper surfaces of the outermost epitaxial source/drain regions 42 of the multiple epitaxial source/drain regions 42. Accordingly, portions of upper surfaces of the outermost epitaxial source/drain regions 42 may be free of the source/drain contact 90. Note that the embodiments shown in FIGS. 29A-29C have only two epitaxial source/drain regions 42, and thus both of the epitaxial source/drain regions 42 shown in FIGS. 29A-29C may be considered “outermost.” In other embodiments in which a single source/drain contact 90 is formed over three or more epitaxial source/drain regions 42, the source/drain contact 90 may completely cover upper surfaces of epitaxial source/drain regions 42 located between the outermost epitaxial source/drain regions 42. In some embodiments, side surfaces of the outermost epitaxial source/drain regions 42 may physically contact the first ILD 86 or may protrude into the first ILD 86, as shown in FIGS. 29A-29C. In some embodiments, bottom regions 51 may be formed underneath the outermost epitaxial source/drain regions 42, as shown in FIG. 29A. The bottom regions 51 may be similar to those described previously for FIG. 27A.

FIG. 29B illustrates an embodiment similar to FIG. 29A, except that air gaps 91 are formed between the isolation regions 22 and the outermost epitaxial source/drain regions 42. The air gaps 91 may be similar to those described previously for FIG. 27B. In some cases, both air gaps 91 and bottom regions 51 may be present between the isolation regions 22 and the outermost epitaxial source/drain regions 42. FIG. 29C illustrates an embodiment similar to FIG. 29B, except that regions underneath the outermost epitaxial source/drain regions 42 are completely filled with the first ILD material 86′, similar to the embodiment shown in FIG. 27C.

FIGS. 30, 31A, 31B, and 31C illustrate embodiments in which a source/drain contact 90 is formed over a merged epitaxial source/drain region 42. For example, FIGS. 30-31C each show a source/drain contact 90 that is physically and electrically connected to a merged epitaxial source/drain region 42 formed of two epitaxial source/drain regions that merged together during the epitaxial growth process. In other embodiments, a merged epitaxial source/drain region 42 may be formed of more than two epitaxial source/drain regions that are merged together. Turning to FIG. 30, an embodiment is shown for which the source/drain contact 90 has a width that is greater than the overall width W5 of the merged epitaxial source/drain region 42. In some embodiments, the conductive material 50 of the source/drain contact 90 may extend underneath outermost portions of the merged epitaxial source/drain region 42. In some embodiments, one or more air gaps 93 may be formed underneath the merged epitaxial source/drain region 42. The air gaps 93 may be formed, for example, underneath regions where adjacent epitaxial source/drain regions merged together during the epitaxial growth process. In this manner, the air gaps 93 may be located between adjacent fins 24, as shown in FIG. 30. The air gaps 93 may have a different size or shape than shown in the figures.

FIGS. 31A-31C show embodiments in which the overall width W5 of the merged epitaxial source/drain regions 42 is larger than a width of the single source/drain contact 90. In some embodiments, the single source/drain contact 90 may partially cover the upper surface of the merged epitaxial source/drain regions 42. Accordingly, portions of upper surface of the merged epitaxial source/drain regions 42 may be free of the source/drain contact 90. In some embodiments, side surfaces of the merged epitaxial source/drain regions 42 may physically contact the first ILD 86 or may protrude into the first ILD 86, as shown in FIGS. 31A-31C. In some embodiments, bottom regions 51 and/or air gaps 93 may be formed underneath the merged epitaxial source/drain regions 42, as shown in FIG. 31A. The bottom regions 51 or air gaps 93 may be similar to those described previously.

FIG. 31B illustrates an embodiment similar to FIG. 31A, except that air gaps 91 and air gaps 93 are formed between the isolation regions 22 and the merged epitaxial source/drain regions 42. The air gaps 91 or air gaps 93 may be similar to those described previously. For example, the air gaps 91 may be formed underneath outermost portions of the merged epitaxial source/drain regions 42, and the air gaps 93 may be formed underneath regions where adjacent epitaxial source/drain regions merged together during the epitaxial growth process. In some cases, both air gaps 91 and bottom regions 51 may be present. FIG. 31C illustrates an embodiment similar to FIG. 31B, except that the regions underneath outermost portions of the merged epitaxial source/drain regions 42 are completely filled with the first ILD material 86′, similar to the embodiments shown in FIGS. 27C and 29C.

The embodiments described herein are described in the context of source/drain contacts for a FinFET, but other conductive features of a FinFET or of other types of devices may be formed using the techniques described herein. For example, the disclosed FinFET embodiments could also be applied to nanostructure devices such as nanostructure (e.g., nanosheet, nanowire, gate-all-around, or the like) field effect transistors (NSFETs). In an NSFET embodiment, the fins are replaced by nanostructures formed by patterning a stack of alternating layers of channel layers and sacrificial layers. Dummy gate stacks and source/drain regions are formed in a manner similar to the above-described embodiments. After the dummy gate stacks are removed, the sacrificial layers can be partially or fully removed in channel regions. The replacement gate structures are formed in a manner similar to the above-described embodiments, the replacement gate structures may partially or completely fill openings left by removing the sacrificial layers, and the replacement gate structures may partially or completely surround the channel layers in the channel regions of the NSFET devices. ILDs and contacts to the replacement gate structures and the source/drain regions may be formed in a manner similar to the above-described embodiments. A nanostructure device can be formed as disclosed in U.S. Patent Application Publication No. 2016/0365414, which is incorporated herein by reference in its entirety.

The embodiments of the present disclosure have some advantageous features. By forming conductive features by first depositing a metal and then patterning the metal, the metal may form having large grain sizes. For example, depositing the metal over a large area to a sufficient thickness can allow larger grains to form in the metal than, for example, depositing the metal into a trench or other bounded region. By depositing the metal to have larger grains, the resistance of the deposited metal may be reduced, for example, by reducing grain boundary scattering. In this manner, conductive features such as source/drain contacts or the like may be formed having less resistance, which can improve a device's speed, improve a device's efficiency, or reduce a device's resistive heating. Additionally, forming source/drain contacts using the techniques described herein can allow for a larger contact area between a source/drain and a source/drain contact. In some cases, a larger contact area can reduce the contact resistance of a source/drain contact, which can provide further device improvement in addition that provided by the larger grain formation described previously.

In accordance with some embodiments of the present disclosure, a method includes forming an isolation region around a semiconductor fin; forming a gate structure over the semiconductor fin; forming a source/drain region in the semiconductor fin adjacent the gate structure; depositing a metal material covering the isolation region, the gate structure, the semiconductor fin, and the source/drain region; etching openings in the metal material, wherein each opening exposes the isolation region, wherein the metal material remains on a top surface of the source/drain region remains after etching the openings; and depositing an insulating material, wherein the insulating material fills the openings. In some embodiments, the method includes depositing a dummy dielectric material over the isolation region before forming the gate structure and removing the dummy dielectric material before depositing the metal material. In some embodiments, the method includes performing a planarization process on the metal material before etching the openings. In some embodiments, after etching the openings, the metal material extends underneath the source/drain region. In some embodiments, the insulating material extends underneath the source/drain region. In some embodiments, etching the openings exposes a surface of the source/drain region. In some embodiments, etching the openings removes the metal material from a region underneath the source/drain region, wherein after depositing the insulating material, an air gap is present in the region underneath the source/drain region. In some embodiments, after etching the openings, an angle between a top surface of the metal material and a sidewall of the metal material is greater than 90°.

In accordance with some embodiments of the present disclosure, a method includes forming source/drain regions in semiconductor fins; depositing a first isolation material over the semiconductor fins and the source/drain regions; forming gate structures, wherein each gate structure extends over at least one semiconductor fin; removing the first isolation material using an etching process; after removing the first isolation material, depositing a metal material over the gate structures, the fins, and the source/drain regions; patterning the metal material to form source/drain contacts on the source/drain regions, wherein each source/drain contact tapers from the bottom of the source/drain contact to the top of the source/drain contact; and depositing a second isolation material over the source/drain contacts, wherein the second isolation material separates adjacent source/drain contacts. In some embodiments, one source/drain contact physically contacts two source/drain regions. In some embodiments, the metal material has an average grain size in the range of 50 nm to 200 nm. In some embodiments, patterning the metal material includes forming a photoresist structure over the metal material; patterning the photoresist structure; and etching the metal material using the patterned photoresist structure as an etching mask. In some embodiments, a sidewall of the second isolation material adjacent a source/drain contact has an angle with respect to a top surface of the second isolation material that is in the range of 85° to 90°. In some embodiments, the source/drain regions are free of the second isolation material. The some embodiments, one source/drain contact has a width that is larger than a width of an underlying source/drain region.

In accordance with some embodiments of the present disclosure, a device includes a first fin protruding from a semiconductor substrate; a gate stack over the first fin; a first source/drain region in the first fin adjacent the gate stack; and a source/drain contact on the first source/drain region, wherein the source/drain contact includes a metal material, wherein the metal material extends on a top surface of the first source/drain region and on an underside surface of the first source/drain region, wherein sidewalls of the source/drain contact are separated by a greater distance near the bottom of the source/drain contact than near the top of the source/drain contact. In some embodiments, a width of the first source/drain region is greater than a width of the source/drain contact. In some embodiments, the device includes a second source/drain region in a second fin, wherein the source/drain contact extends on a top surface of the second source/drain region. In some embodiments, the metal material extends from the underside surface of the first source/drain region to an underside surface of the second source/drain region. In some embodiments, the metal material has a grain size in the range of 50 nm to 200 nm. The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A device comprising:
a first fin protruding from a semiconductor substrate;
a gate stack over the first fin;
a first source/drain region in the first fin adjacent the gate stack; and
a source/drain contact on the first source/drain region, wherein the source/drain contact comprises a metal material, wherein the metal material extends on a top surface of the first source/drain region and on an underside surface of the first source/drain region, wherein sidewalls of the source/drain contact are separated by a greater distance near the bottom of the source/drain contact than near the top of the source/drain contact.

2. The device of claim 1, wherein a width of the first source/drain region is greater than a width of the source/drain contact.

3. The device of claim 1 further comprising a second source/drain region in a second fin, wherein the source/drain contact extends on a top surface of the second source/drain region.

4. The device of claim 3, wherein the metal material extends from the underside surface of the first source/drain region to an underside surface of the second source/drain region.

5. The device of claim 1, wherein the metal material has a grain size in the range of 50 nm to 200 nm.

6. The device of claim 3 wherein the first source/drain region and the second source/drain region are merged.

7. The device of claim 6 further comprising an air gap underneath the first source/drain region and the second source/drain region.

8. The device of claim 1, wherein the sidewalls of the source/drain contact are straight.

9. A device comprising:
a first semiconductor fin on a substrate;
a second semiconductor fin adjacent the first semiconductor fin;
a first isolation region surrounding the first semiconductor fin and the second semiconductor fin;
a first epitaxial region on the first semiconductor fin, wherein the first epitaxial region overhangs the first isolation region;
a second epitaxial region on the second semiconductor fin, wherein the second epitaxial region overhangs the first isolation region;
a first metal feature on a top surface of the first isolation region, wherein the first metal feature extends continuously over a top surface of the first epitaxial region and over a top surface of the second epitaxial region, wherein the first epitaxial region is laterally separated from the second epitaxial region by the first metal feature; and
a second isolation region surrounding the first epitaxial region, the second epitaxial region, and the first metal feature, wherein a first width of the first metal feature at the first epitaxial region and the second epitaxial region is larger than a second width of the first metal feature at a top surface of the second isolation region.

10. The device of claim 9 further comprising a first silicide layer between the first epitaxial region and the first metal feature.

11. The device of claim 9, wherein the first metal feature directly contacts the first epitaxial region and the second epitaxial region.

12. The device of claim 9, wherein top surfaces of the first metal feature and the second isolation region are level.

13. The device of claim 9 further comprising an air gap between the first epitaxial region and the first metal feature.

14. The device of claim 9, wherein the second isolation region directly contacts the first epitaxial region.

15. The device of claim 9, wherein the first width of the first metal feature at the first epitaxial region and the second epitaxial region is smaller than a third width of the first metal feature at a top surface of the first isolation region.

16. A device comprising:
a first epitaxial region on a first fin;
a first silicide region on a top surface of the first epitaxial region;
a first contact on the first silicide region, wherein the first contact comprises a metal having a grain size in the range of 50 nm to 200 nm, wherein the first contact extends underneath the first epitaxial region; and
a dielectric layer covering a first sidewall of the first contact, wherein an angle between a top surface of the dielectric layer and the first sidewall is less than 90°

17. The device of claim 16, wherein the dielectric layer directly contacts the first silicide region.

18. The device of claim 16, wherein the dielectric layer directly contacts the first epitaxial region.

19. The device of claim 16 wherein the dielectric layer directly contacts a grain of the first contact.

20. The device of claim 16, wherein a width of a bottom surface of the dielectric layer is smaller than a width of a top surface of the dielectric layer.
